(19) United States
(12) Patent Application Publication
(10) Pub. No.: US 2004/0065257 A1
(43) Pub. Date: Apr. 8, 2004

(54) Self-aligning PVD mark shield

(75) Inventors: Jen-Hung Huang, Kaohsiung (TW); Wu-Xing Lin, Yunlin (TW); Jiunn-Kae Chiang, Tainan (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 10/266,044

(22) Filed: Oct. 7, 2002

(51) Int. Cl. C23C 16/00

(52) U.S. Cl. 118/721; 118/728

(57) ABSTRACT

A new and improved, self-aligning mark shield for PVD chambers. The mark shield of the present invention comprises an annular body having a retainer flange for engaging and retaining a substrate on a substrate support of a process chamber. An annular locating pin is provided on the bottom surface of the body for engaging the substrate support and preventing excessive X- and Y-axis movement of the substrate on the substrate support. The mark shield obviates the need for a standard ceramic isolation assembly to maintain the mark shield in position in the chamber.

### FIELD OF THE INVENTION

The present invention relates to mark shields for aligning substrates on a wafer support in a PVD (physical vapor deposition) chamber for the fabrication of integrated circuits on the substrate. More particularly, the present invention relates to a self-aligning mark shield for a process chamber.

### BACKGROUND OF THE INVENTION

In the fabrication of semiconductor integrated circuits, metal conductor lines are used to interconnect the multiple components in device circuits on a semiconductor wafer. A general process used in the deposition of metal conductor line patterns on semiconductor wafers includes deposition of a conducting layer on the silicon wafer substrate; formation of a photoresist or other mask such as titanium oxide or silicon oxide, in the form of the desired metal conductor line pattern, using standard lithographic techniques; subjecting the wafer substrate to a dry etching process to remove the conducting layer from the areas not covered by the mask, thereby leaving the metal layer in the form of the masked conductor line pattern; and removing the mask layer typically using reactive plasma and chlorine gas, thereby exposing the top surface of the metal conductor lines. Typically, multiple alternating layers of electrically conductive and insulative materials are sequentially deposited on the wafer substrate, and conductive layers at different levels on the wafer may be electrically connected to each other by etching vias, or openings, in the insulative layers and filling the vias using aluminum, tungsten or other metal to establish electrical connection between the conductive layers.

Laser marks are typically embedded in the substrate at the beginning of processing. The laser marks contain certain information necessary for later identification of the substrate, such as lot number and job number. These marks must be kept visible during wafer processing. For some substrates, the laser marks are located in the saw kerf adjacent to the integrated circuit dice, in which case the marks identify locations of die on the substrate. For other substrates, only one set of laser marks are provided on each substrate, typically in a region where integrated circuit die cannot be fabricated, such as adjacent to the edge of the substrate.

In semiconductor production, the quality of the integrated circuits on the semiconductor wafer is directly correlated with the purity of the fabricating processes, which in turn depends upon the cleanliness of the manufacturing environment. Furthermore, technological advances in recent years in the increasing miniaturization of semiconductor circuits necessitate correspondingly stringent control of impurities and contaminants in the plasma process chamber. When the circuits on a wafer are submicron in size, the smallest quantity of contaminants can significantly reduce the yield of the wafers. For instance, the presence of particles during deposition or etching of thin films can cause voids, dislocations, or short-circuits which adversely affect performance and reliability of the devices constructed with the circuits.

Particle and film contamination has been significantly reduced in the semiconductor industry by improving the quality of clean rooms, by using automated equipment designed to handle semiconductor substrates, and by improving techniques used to clean the substrate surfaces. However, as deposit of material on the interior surfaces of the processing chamber remains a problem, various techniques for in-situ cleaning of process chambers have been developed in recent years. Cleaning gases such as nitrogen trifluoride, chlorine trifluoride, hexafluoroethane, sulfur hexafluoride and carbon tetrafluoride and mixtures thereof have been used in various cleaning applications. These gases are introduced into a process chamber at a predetermined temperature and pressure for a desirable length of time to clean the surfaces inside a process chamber. However, these cleaning techniques are not always effective in cleaning or dislodging all the film and particle contaminants coated on the chamber walls and interior chamber components. The smallest quantity of contaminants remaining in the chamber after such cleaning processes can cause significant problems in subsequent manufacturing cycles.

Deposition of conductive layers on the wafer substrate can be carried out using any of a variety of techniques. These include oxidation, LPCVD (low-pressure chemical vapor deposition), APCVD (atmospheric-pressure chemical vapor deposition), and PECVD (plasma-enhanced chemical vapor deposition). In general, chemical vapor deposition involves reacting vapor-phase chemicals that contain the required deposition constituents with each other to form a nonvolatile film on the wafer substrate. Chemical vapor deposition is the most widely-used method of depositing films on wafer substrates in the fabrication of integrated circuits on the substrates.

Physical vapor deposition (PVD) is another technique used in the deposition of conductive layers, particularly metal layers, on a substrate. Physical vapor deposition includes techniques such as filament evaporation and electron beam evaporation and, most recently, sputtering. In a sputtering process, high-energy particles strike a solid slab of high-purity target material and physically dislodge atoms from the target. The sputtered atoms are deposited on the substrate.

FIG. 1 illustrates a typical standard physical vapor deposition chamber 10. The PVD chamber 10 includes a chamber wall 12 which defines a chamber interior 14. A susceptor 16 supports a substrate 30 in the chamber interior 14. A metal target 20 is disposed beneath a cathode 18 in the top of the chamber interior 14.

A process kit 21 is typically provided in the chamber interior 14 to prevent titanium and titanium compounds from depositing on the inner surfaces of the chamber wall 12 during a PVD process. A standard-type process kit 21 may include an annular mark shield 22 which is provided with an annular retainer flange 23 that shields or covers identifying marks (not shown) provided in the surface of the substrate 30, typically adjacent to the edge thereof. A pair of rod screws 28 extends downwardly from the mark shield 22, and each rod screw 28 extends through a rod screw opening 27 provided in a corresponding ceramic isolation assembly 26 which is mounted in the bottom portion of a cylindrical low shield 24 that may be mounted to the chamber wall 12. The isolation assemblies 26 and rod screws 28 function to align the mark shield 22 with respect to the substrate 30 in such a manner that the retainer flange 23 normally shields or covers the identification and other markings adjacent to the edge of the substrate 30.

In a typical titanium nitride deposition process, the substrate 30 is placed on the susceptor 16 and nitrogen gas and an inert gas (typically argon) enter the chamber interior 14 through a gas inlet (not shown). A power supply (not shown) applies a negative potential to the titanium target 20, and the substrate 30 functions as an anode having a net positive charge. Consequently, an electric field is created in the chamber interior 14, and a plasma is generated from the nitrogen and inert gas. A high density of positive ions from the plasma is strongly attracted to the negative target material, striking the target at high velocity. The titanium atoms are sputtered, or knocked off, the titanium target 20 and scatter in the chamber interior 14, reacting with nitrogen atoms and nitrogen ions formed in the plasma to produce titanium nitride particles. Some of the titanium nitride particles are deposited on the substrate 30, where the atoms nucleate and form a thin film, whereas other titanium nitride particles are deposited on the elements of the process kit 21.

During deposition processes such as titanium nitride film deposition, the thin metal films are inevitably formed over the interior surfaces of the chamber walls 12, as well as on other components in the chamber interior 14. One of the problems inherent in operation of the standard mark shield 22 is that the mark shield 22 tends to shift along the X and Y axes in the chamber interior 14 during the ion sputtering process, since the rod screw openings 27 present a tolerance of 1.6 mm. This may cause film deposits on the mark shield 22 to flake off and fall on the substrate 30, adversely affecting both the yield and reliability of the devices fabricated on the substrate 30. Furthermore, the identifying or other markings on the substrate 30 may shift out from under the retainer flange 23 of the mark shield 22 and be exposed to and covered by the deposited material layer or layers. When the anode 16 is biased during post deposition plasma annealing, film deposits formed on the surfaces of mark shield 22 cause micro-arcing from the film deposit to the chamber wall 12. Such micro-arcing introduces contaminants into the chamber interior 14. Consequently, the standard process kit 21 has a lifetime of approximately 180˜190 kw-h, and the wafer count throughout the lifetime of the standard process kit 21 is about 1800-1900 pieces.

Accordingly, an object of the present invention is to provide a new and improved mark shield for PVD chambers.

Another object of the present invention is to provide a new and improved, self-aligning mark shield for PVD chambers.

Still another object of the present invention is to provide a PVD chamber mark shield which has increased longevity.

Yet another object of the present invention is to provide a new and improved mark shield which prevents micro-arcing during a PVD process.

Still another object of the present invention is to provide a mark shield which stabilizes a substrate along the X and Y axes during a PVD process.

Yet another object of the present invention is to provide a PVD chamber mark shield which is characterized by low cost.

A still further object of the present invention is to provide a PVD chamber mark shield which prevents or reduces contamination and scrapping of substrates.

### SUMMARY OF THE INVENTION

In accordance with these and other objects and advantages, the present invention is generally directed to a new and improved, self-aligning mark shield for PVD chambers. The mark shield of the present invention comprises an annular body having a retainer flange for engaging and retaining a substrate on a substrate support of a process chamber. An annular locating pin is provided on the bottom surface of the body for engaging the substrate support and preventing excessive X- and Y-axis movement of the substrate on the substrate support. The mark shield obviates the need for a standard ceramic isolation assembly to maintain the mark shield in position in the chamber.

### BRIEF DESCRIPTION OF THE DRAWINGS

The invention will now be described, by way of example, with reference to the accompanying drawings, in which:

FIG. 1 is a cross-sectional view of a conventional physical vapor deposition process chamber, with a standard mark shield of a heater assembly mounted in the chamber;

FIG. 2 is a bottom view of an illustrative embodiment of a self-aligning mark shield of the present invention;

FIG. 3 is a top view of an illustrative embodiment of the mark shield of the present invention; and

FIG. 4 is a cross-sectional view of a conventional PVD process chamber and a mark shield of the present invention mounted in functional position in the process chamber.

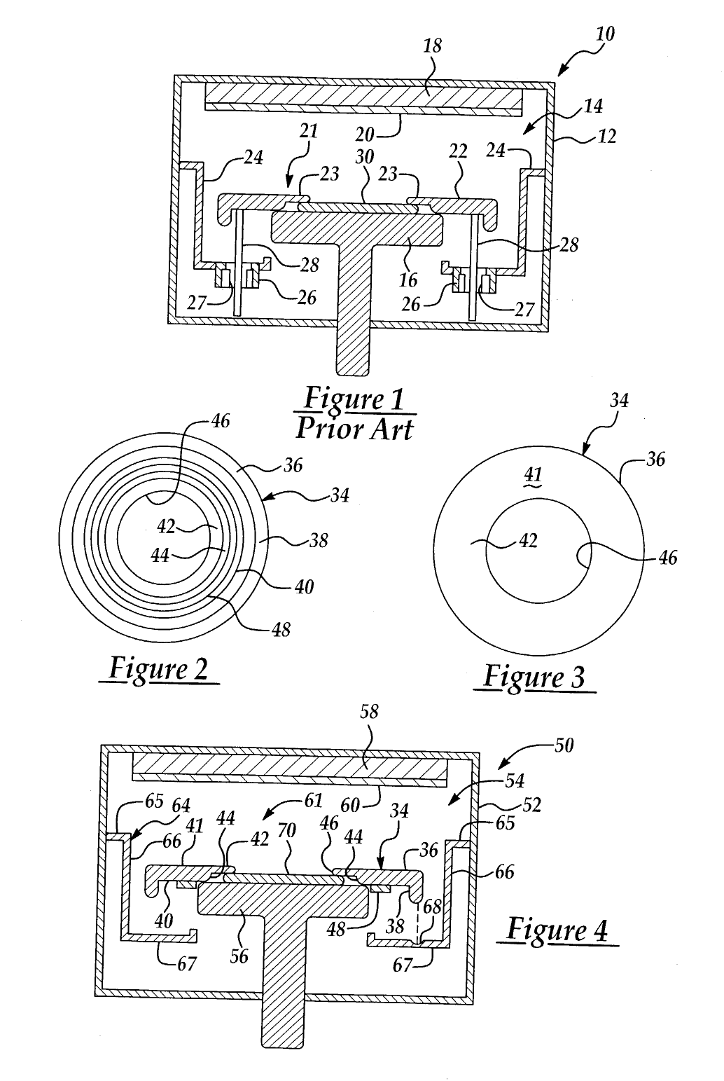

### DESCRIPTION OF THE PREFERRED EMBODIMENTS

The present invention has particularly beneficial utility in preventing micro-arcing and contamination of substrates in a PVD process chamber during a physical vapor deposition process. However, the invention is not so limited in application, and while references may be made to such PVD process chamber, the invention is more generally applicable to preventing micro-arcing and resultant contamination in a variety of process chambers for the fabrication of semiconductors.

Referring initially to FIG. 4, the mark shield 34 of the present invention is particularly suitable for shielding identifying or other markings (not shown) on a substrate 70 as the substrate 70 is subjected to a physical vapor deposition (PVD) process carried out in a PVD chamber 50. The PVD chamber 50 includes a chamber wall 52 which defines a chamber interior 54. A susceptor 56 supports the substrate 70 in the chamber interior 54. A metal target 60, typically of titanium, is disposed beneath a cathode 58 in the top of the chamber interior 54.

Referring to FIGS. 2-4, the mark shield 34 of the present invention includes an annular body 36 having a bottom surface 40 and a top surface 41. A retainer flange 42 extends from the body 36 and defines a central opening 46. As shown in FIG. 4, the retainer flange 42 typically extends from an annular bevel 44 shaped in the underside of the body 36. An annular bottom flange 38 extends downwardly from the outer edge of the body 36. A locating pin 48, which may be annular, extends downwardly from the bottom surface 40, between the bottom flange 38 and the bevel 44.

As shown in FIG. 4, the mark shield 34 may be used as a component part of a process kit 61 which includes a low shield 64 for preventing or minimizing deposit of titanium nitride films on the interior surfaces of the chamber wall 52. The low shield 64 may include an annular attachment portion 65 which is mounted to the chamber wall 52; an annular vertical portion 66 which extends downwardly from the attachment portion 65; and an annular horizontal portion 67 which extends inwardly from the vertical portion 66. In accordance with the present invention, an alignment notch 68 may be provided in the upper surface of the horizontal portion 67 for purposes which will be hereinafter described. The alignment notch 68 may alternatively be an opening extending through the horizontal portion 67 or any other suitable marking on the horizontal portion 67.

Referring again to FIG. 4, in a typical PVD process in application of the mark shield 34, a substrate 70 is initially placed and centered on the susceptor 56 in the chamber interior 54. The mark shield 34 is then placed on the susceptor 56, with the retainer flange 42 of the mark shield 34 engaging the upper surface of the substrate 70 along the edge thereof, such that the retainer flange 42 covers identifying and other markings (not shown) previously cut in the surface of the substrate 70. Accordingly, the remaining portion of the substrate 70 is exposed through the central opening 46 of the mark shield 34. As the mark shield 34 is placed on the susceptor 56, the bottom flange 38 is aligned with the alignment notch 68 in the horizontal portion 67 of the low shield 64. This ensures that the retainer flange 42 of the mark shield 34 properly engages the substrate 70 and covers the markings thereon. As further shown in FIG. 4, by engaging the edges of the susceptor 56, the locating pin 48 prevents inadvertent shifting of the mark shield 34 along the X and Y axes on the susceptor 56, thereby preventing uncovering of the markings on the substrate 70 by the retainer flange 42 of the mark shield 34 and further preventing micro-arcing during the PVD process.

It will be appreciated by those skilled in the art that the X and Y axis tolerances of the mark shield 34 on the susceptor 56 are typically about 0.4 mm, and this substantially limits X and Y axis movement of the mark shield 34 on the susceptor 56 and with respect to the substrate 70 during the PVD process. Consequently, microarcing in the chamber interior 54 during the PVD process is eliminated. The process kit 61 incorporating the mark shield 34 of the present invention has a lifetime of typically greater than 245 kw-h, as compared to 180˜190 kw-h for the standard process kit. The wafer count throughout the lifetime of the process kit 61 incorporating the mark shield 34 of the present invention is greater than 2450 pieces, as compared to 1800˜1900 pieces for the standard process kit. Furthermore, due to the ease of installation, the process kit 61 including the mark shield 34 of the present invention can be installed in a shorter period of time, typically about 30 minutes, as compared to the installation time for the standard process kit, which is typically about 40 minutes.

While the preferred embodiments of the invention have been described above, it will be recognized and understood that various modifications can be made in the invention and the appended claims are intended to cover all such modifications which may fall within the spirit and scope of the invention.

What is claimed is:

1. A mark shield for engaging a substrate on a substrate support in a process chamber, comprising:
a body for engaging the substrate; and
a locating pin carried by said body for engaging the substrate support and substantially preventing shifting of the substrate on the substrate support.

2. The mark shield of claim 1 wherein said locating pin has an annular configuration.

3. The mark shield of claim 1 further comprising a retainer flange extending from said body for engaging the substrate.

4. The mark shield of claim 3 wherein said locating pin has an annular configuration.

5. The mark shield of claim 1 further comprising a bottom flange extending from said body for aligning said body on the substrate.

6. The mark shield of claim 5 wherein said locating pin has an annular configuration.

7. The mark shield of claim 5 further comprising a retainer flange extending from said body for engaging the substrate.

8. The mark shield of claim 7 wherein said locating pin has an annular configuration.

9. A process kit for engaging a substrate on a substrate support in a process chamber and preventing deposition of a film on chamber walls in the process chamber, said process kit comprising:
a low shield for mounting in the process chamber and preventing deposition of the film on the chamber walls;
a mark shield comprising a body for engaging the substrate and a locating pin carried by said body for engaging the substrate support and substantially preventing shifting of the substrate on the substrate support; and
an alignment mark provided on said low shield for aligning said body on the substrate.

10. The process kit of claim 9 wherein said locating pin has an annular configuration.

11. The process kit of claim 9 further comprising a retainer flange extending from said body for engaging the substrate.

12. The process kit of claim 11 wherein said locating pin has an annular configuration.

13. The process kit of claim 9 further comprising a bottom flange extending from said body for alignment with said alignment mark and aligning said body on the substrate.

14. The process kit of claim 13 wherein said locating pin has an annular configuration.

15. The process kit of claim 13 further comprising a retainer flange extending from said body for engaging the substrate.

16. The process kit of claim 15 wherein said locating pin has an annular configuration.

17. A method of preventing movement of a mark shield on a substrate supported on a substrate support in a process chamber, comprising the steps of:
providing a locating pin on the mark shield; and
engaging said locating pin with the substrate support for preventing inadvertent movement of the mark shield with respect to the substrate.

18. The method of claim 17 wherein said locating pin has an annular configuration.

19. The method of claim 17 further comprising the steps of providing a low shield in the process chamber; providing an alignment mark on said low shield; providing a bottom flange on said mark shield; and aligning said bottom flange with said alignment mark to position said mark shield with respect to the substrate.

20. The method of claim 19 wherein said locating pin has an annular configuration.
